(19) United States
(12) Patent Application Publication
(10) Pub. No.: US 2018/0158742 A1
(43) Pub. Date: Jun. 7, 2018

(54) THROUGH-SILICON VIA BASED SEMICONDUCTOR PACKAGE

(71) Applicant: SHIN SUNG C&T CO., LTD., Seoul (KR)

(72) Inventors: Ci Moo SONG, Yongin-si (KR); Keun Jung YOUN, Dong-gu (KR); Jeong Sik KANG, Seoul (KR); Yong Kook KIM, Seoul (KR)

(73) Assignee: SHIN SUNG C&T CO., LTD., Seoul (KR)

(21) Appl. No.: 15/866,586

(22) Filed: Jan. 10, 2018

Related U.S. Application Data
(63) Continuation of application No. PCT/KR2016/006875, filed on Jun. 28, 2016.

(30) Foreign Application Priority Data
Jul. 13, 2015 (KR) 10-2015-0098963

(51) Int. Cl. H01L 23/053; H01L 23/50; H01L 23/31; H01L 23/48; H01L 23/488

(52) U.S. Cl. CPC H01L 23/053; H01L 23/50; H01L 23/488; H01L 23/481; H01L 23/31

(57) ABSTRACT

Provided is a semiconductor package. The semiconductor package comprises: a device substrate having a device pattern formed thereon; a cap substrate overlying the device substrate and comprising a first cavity area; a base substrate underlying the device substrate and comprising a second cavity area formed in the position corresponding to the first cavity area and at least one first through-silicon via that outputs, to the outside, an electrical signal provided from the device pattern or transmits, to the device pattern, an electrical signal provided from the outside; and a circuit substrate underlying the base substrate and electrically connected with the first through-silicon via to process an electrical signal for the device pattern.

### CROSS-REFERENCE

This application is a continuation application of international application PCT/KR2016/006875, filed on Jun. 28, 2016, now pending, which claims foreign priority from Korean Patent Application No. 10-2015-0098963 filed on Jul. 13, 2015 in the Korean Intellectual Property Office, the disclosure of each document is incorporated herein by reference in their entirety.

### TECHNICAL FIELD

The present disclosure relates to a through-silicon via based semiconductor package.

### BACKGROUND ART

Recently, as the market for portable electronic devices such as smart phones, smart pads, and the like has grown, demand for semiconductor packages that correspond to light, thin, short, and small products has been gradually increasing.

A through-silicon via (TSV) based stacked package (package on package (PoP)) is used as one of semiconductor packages for corresponding to light, thin, short, and small products. In the TSV based stacked package (TSV based PoP), an expandable substrate (e.g., an interposer) is inserted between a lower substrate and an upper substrate each having a TSV based semiconductor die.

Here, an interposer can serve to re-arrange a plurality of lower I/O terminals formed on the lower substrate such that an I/O terminal can be formed in an inner space of a chip attached to the upper substrate. That is, in a stacked package, since an I/O terminal can be formed in an inner space of a chip by inserting an interposer between a lower substrate and an upper substrate, space efficiency for the I/O terminal can be increased.

### DISCLOSURE

### Technical Problems

Aspects of the present disclosure provide a semiconductor package for enabling signal transmission between an inside of a micro-electro-mechanical systems (MEMS) based device pattern and an outside of a base substrate by applying an interconnection method using a through-silicon via (TSV) and by bonding the base substrate to a separately manufactured signal processing integrated circuit (IC) substrate using a substrate to substrate bonding method or a wafer to wafer bonding method.

Aspects of the present disclosure also provide a semiconductor package for enabling signal transmission between an inside of a MEMS based device pattern and an outside of a base substrate by applying an interconnection method using a TSV, forming a TSV in each of a peripheral area of a device substrate and a peripheral area of a cap substrate so as to not physically affect the device pattern, and bonding a separately manufactured signal processing IC substrate to the cap substrate using a substrate to substrate bonding method or a wafer to wafer bonding method.

It should be noted that objects of the present disclosure are not limited to the above-described objects, and other objects of the present disclosure will be apparent to those skilled in the art from the following descriptions.

### Technical Solutions

One aspect of the present disclosure provides a semiconductor package including a device substrate having a device pattern formed thereon, a cap substrate disposed above the device substrate and including a first cavity area, a base substrate disposed below the device substrate and including a second cavity area formed at a position corresponding to the first cavity area and at least one first TSV configured to output an electrical signal provided from the device pattern to the outside or transmit an electrical signal provided from the outside to the device pattern, and a circuit substrate disposed below the base substrate, electrically connected to the first TSV, and configured to process an electrical signal for the device pattern.

The first cavity area may be formed to have a step with respect to a surface of the cap substrate and the second cavity area may be formed to have a step with respect to a surface of the base substrate.

The semiconductor package may further include a metal pad or an electrical insulating layer disposed between the cap substrate and the device substrate and configured to bond the cap substrate to the device substrate.

The semiconductor package may further include a first solder ball disposed between the base substrate and the circuit substrate and configured to electrically connect the base substrate to the circuit substrate.

A melting point of a material which forms the metal pad or the electrical insulating layer may be higher than a melting point of a material which forms the first solder ball.

The semiconductor package may further include a second solder ball disposed below the circuit substrate, and the melting point of the material which forms the first solder ball may be higher than a melting point of a material which forms the second solder ball.

The device substrate and the base substrate may be electrically connected by a wafer to wafer bonding method.

The first cavity area may include one or more cavity areas and the one or more cavity areas may be separated from each other by a first hermetic sealing wall formed by the cap substrate and the device substrate.

At least one vertical electrode may be formed in the second cavity area.

The second cavity area may include one or more cavity areas and the one or more cavity areas may be separated from each other by a second hermetic sealing wall formed by the device substrate and the base substrate.

Another aspect of the present disclosure provides a semiconductor package including a device substrate having a device pattern formed thereon, a cap substrate disposed above the device substrate and including first cavity areas formed therein, a base substrate disposed below the device substrate and including second cavity areas and a first TSV formed therein, and a circuit substrate disposed below the base substrate and including a second TSV formed therein.

The first cavity area may include one or more cavity areas and the one or more cavity areas may be separated from each other by a first hermetic sealing wall formed by the cap substrate and the device substrate.

The second cavity area may include one or more cavity areas and the one or more cavity areas may be separated from each other by a second hermetic sealing wall formed by the device substrate and the base substrate.

The second TSV may be formed at a position corresponding to a lower portion of the second hermetic sealing wall.

The second TSV may include a plurality of TSVs and the plurality of TSVs may be disposed in a point symmetry structure with respect to a center of the circuit substrate.

A first vertical electrode or a first lateral electrode may be formed in the second cavity area to sense an electrical signal of the device pattern.

The first TSV may be electrically connected to the first vertical electrode or the first lateral electrode.

A second vertical electrode or a second lateral electrode may be formed in the second cavity area to transmit an electrical signal to the device pattern and drive the device pattern.

The first TSV may be electrically connected to the second vertical electrode or the second lateral electrode.

The first TSV and the second TSV may be electrically connected.

The first cavity areas may be formed to have a step with respect to a surface of the cap substrate, and the second cavity area may be formed to have a step with respect to a surface of the base substrate.

The first cavity areas may be a hermetic space formed by bonding the cap substrate and the device substrate using a wafer to wafer bonding method.

The second cavity area may be a hermetic space formed by bonding the device substrate and the base substrate using a wafer to wafer bonding method, and an inside and an outside of the second cavity area may be electrically connected using the first TSV.

The base substrate and the circuit substrate may be electrically connected by a wafer to wafer bonding method, and an external electric signal may be transmitted through the second TSV to the device pattern or an electric signal generated from the device pattern may be output to the outside.

The circuit substrate may include a Read Out IC configured to process an electrical signal for the device pattern.

Other specific details of the present disclosure are included in the detailed description and the drawings.

### Advantageous Effects

According to the semiconductor package of the present invention, it is possible to form a through-silicon via on a base substrate and directly connect the base substrate and the integrated circuit substrate by a wafer to wafer bonding method, and it is possible to improve the signal to noise ratio (SNR) to the external input noise and the electrical contact reliability of the electrical signal transmission path by minimizing the electric signal transmission path between the internal device pattern and the external integrated circuit substrate.

Further, the overall size of the semiconductor package can be reduced, and the durability can be improved.

### BRIEF DESCRIPTION OF DRAWINGS

FIG. 1 is a cross-sectional view of a semiconductor package according to an embodiment of the present disclosure;

FIG. 2 is a cross-sectional view of a semiconductor package according to another embodiment of the present disclosure;

FIG. 3 is a cross-sectional view of a semiconductor package according to still another embodiment of the present disclosure;

FIG. 4 is a cross-sectional view of a semiconductor package according to yet another embodiment of the present disclosure;

FIG. 5 is a plan view of a semiconductor package according to yet another embodiment of the present disclosure; and

FIGS. 6, 7, 8, 9, 10, 11, 12, & 13 are views illustrating intermediate steps for describing a method of manufacturing a semiconductor device according to an embodiment of the present disclosure.

### BEST MODES FOR CARRYING OUT THE INVENTION

Advantages and features of the present disclosure and methods of achieving the same will be clearly understood with reference to the accompanying drawings and embodiments described in detail below. However, the present disclosure is not limited to the embodiments to be disclosed below, but may be implemented in various different forms. The embodiments are provided in order to fully explain the present embodiments and fully explain the scope of the present embodiments for those skilled in the art. The scope of the present embodiments is only defined by the appended claims. Like reference numerals refer to like elements throughout the specification.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. As used herein, the term “and/or” includes any and all combinations of one or more of the associated listed items.

When an element is referred to as being disposed “on” other element, another element may be interposed directly on the other element or therebetween. In contrast, when an element is referred to as being “directly on” or “immediately on,” no intervening elements may be present.

The spatially-relative terms such as “below,” “beneath,” “lower,” “above,” and “upper” may be used herein for ease of description to describe the relationship of one element or components with another element(s) or component(s) as illustrated in the drawings. The spatially relative term should be understood to include different directions of the element which is used or operates, in addition to the direction illustrated in the drawing. For example, if the element in the drawings is turned over, elements described as “below” or “beneath” other elements would then be oriented “above” the other elements. Therefore, an exemplary term “below” may encompass both an orientation of above and below. The elements can also be oriented in different directions, so that spatially relative terms can be interpreted according to orientation.

Meanwhile, the terms used herein are provided to only describe embodiments of the present disclosure and not for purposes of limitation. Unless the context clearly indicates otherwise, the singular forms include the plural forms. It will be understood that the terms “comprise” or “comprising” when used herein, specify some stated components, steps, operations and/or elements, but do not preclude the presence or addition of one or more other components, steps, operations and/or elements.

While such terms as “first,” “second,” etc., may be used to describe various elements, such elements must not be limited to the above terms. The above terms are used only to distinguish one element from another. Therefore, a first element to be described below may be a second element within the technical spirit of the present disclosure.

Unless otherwise defined, all terms (including technical and scientific terms) used herein can be used as is customary in the art to which this disclosure belongs. Also, It will be further understood that terms, such as those defined in commonly used dictionaries, will not be interpreted in an idealized or overly formal sense unless expressly so defined herein.

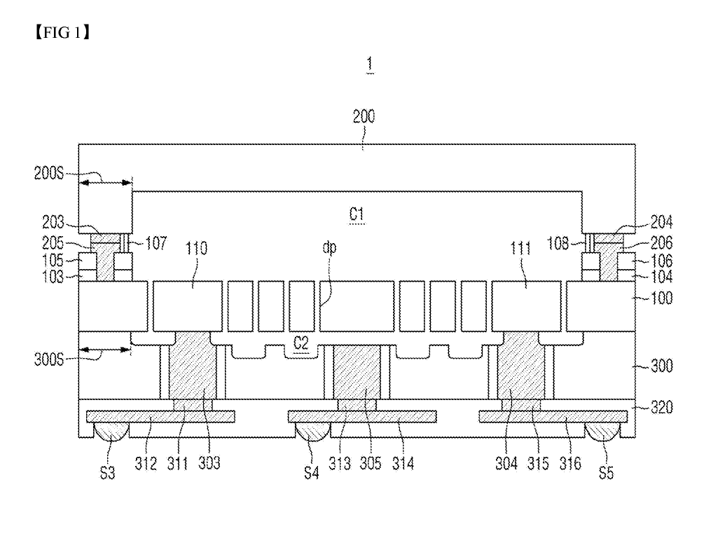

FIG. 1 is a cross-sectional view of a semiconductor package according to an embodiment of the present disclosure.

Referring to FIG. 1, a semiconductor package 1 includes a device substrate 100, a cap substrate 200, and a base substrate 300.

A micro-electro-mechanical systems (MEMS) based device pattern dp may be formed on the device substrate 100. The MEMS is generally referred to as a microelectromechanical system, microelectronic control technology, etc., and refers to a micrometer (μm) or millimeter (mm) scale micromachining process technology based on semiconductor processing technology. For example, the device pattern dp may be a MEMS based X-Y axis gyroscope or Z axis gyroscope. The device substrate 100 may be a low resistance silicon wafer of about 0.01 Ωcm, but the present disclosure is not limited thereto.

Passivation films 103 and 104 may be formed on the device substrate 100. A chemical vapor deposition (CVD) process, an atomic layer deposition (ALD) process, a physical vapor deposition (PVD) process, a plasma-enhanced CVD (PECVD) process, a low pressure CVD (LPCVD) process, a pulsed CVD (P-CVD) process, or a combination thereof may be used as a deposition process for forming the passivation films 103 and 104.

In some embodiments of the present disclosure, a deposition gas may be supplied onto the device substrate 100 in order to form, using a CVD or ALD process, passivation films 103 and 104 which are made of a metal nitride film containing Ru and N. The deposition gas may include a Ru precursor and a nitrogen source. A carrier gas (e.g., an inert gas), a reducing gas, or a combination thereof may be supplied with the deposition gas.

For example, the Ru precursor includes Ru₃(CO)₁₂, Ru(DMPD)(EtCp) ((2,4-dimethylpentadienyl)(ethylcyclopentadienyl)ruthenium), Ru(DMPD)₂ (bis(2,4-dimethylpentadienyl)ruthenium), Ru(DMPD)(MeCp) (4-dimethylpentadienyl)(methylcyclopentadienyl)ruthenium), and Ru(EtCp)₂) (bis(ethylcyclopentadienyl)ruthenium), but the present disclosure is not limited thereto.

The nitrogen source may be selected from a group consisting of nitrogen (N₂) gas, nitrogen monoxide (NO) gas, dinitrogen monoxide (N₂O) gas, nitrogen dioxide (NO₂) gas, ammonia (NH₃) gas, N-containing radical (e.g., N*, NH*, or NH₂*), amines, and a combination thereof, but the present disclosure is not limited thereto.

In some embodiments, when N₂ gas is used as the nitrogen source, passivation films 103 and 104 which are made of ruthenium nitride may be obtained. In other embodiments, when NO₂ gas is used as the nitrogen source, passivation films 103 and 104 which are made of ruthenium oxynitride may be obtained.

Solder pads 105 and 106 may be formed on the passivation films 103 and 104, respectively. The solder pads 105 and 106 may be formed as a gold (Au) layer using an electrolytic plating method, but the present disclosure is not limited thereto. Solder contacts 205 and 206 may be formed on the solder pads 105 and 106, respectively, so that the cap substrate 200 thereabove and the device substrate 100 therebelow may be electrically connected. Specifically, metal pads 203 and 204 may be formed on the cap substrate 200 and the metal pads 203 and 204 may be brought into contact with the solder contacts 205 and 206, respectively, so that the cap substrate 200 thereabove and the device substrate 100 therebelow may be electrically connected. The metal pads 203 and 204 may be formed, for example, by performing electroplating on a seed layer.

The cap substrate 200 may be disposed above the device substrate 100, and a first cavity area C1 may be formed in the cap substrate 200. The cap substrate 200 may be mechanically connected to the device substrate 100 by a wafer to wafer bonding method. The first cavity area C1 may be a hermetic space formed by bonding the cap substrate 200 to the device substrate 100 using the wafer to wafer bonding method.

The first cavity area C1 may be formed to have a step with respect to a surface of the cap substrate 200. That is, a portion of the surface of the cap substrate 200 may be etched to form an empty space, and the empty space may be the first cavity area C1. The first cavity area C1 is formed to correspond to an area in which the device pattern dp is formed on the device substrate 100 so that the first cavity area C1 serves to provide a space in which the device pattern dp can vibrate when the device pattern dp vibrates up, down, left, and right. For example, the device pattern dp may be an X-Y axis gyroscope or a Z axis gyroscope, and such a device pattern dp may vibrate up, down, left, and right according to a movement of a user.

One or more first cavity areas C1 may be formed. Since the device pattern dp formed on the device substrate 100 may have a complex shape and a plurality of areas in which the device pattern dp vibrates may be present, the one or more first cavity areas C1 may be formed to correspond to a position at which the device pattern dp vibrates.

When a plurality of first cavity areas C1 are formed, the cavity areas may be separated from each other by a first sealing wall 200s formed by the cap substrate 200 and the device substrate 100.

The base substrate 300 may be disposed below the device substrate 100, a second cavity area C2 may be formed on the base substrate 300, and first through-silicon vias (TSVs) 303, 304, and 305 may be formed in the base substrate 300. The first TSVs 303, 304, and 305 may serve to output an electrical signal provided from the device pattern dp to the outside or transmit an electrical signal provided from the outside to the device pattern dp. Further, connection pads 311, 313, and 315 may be formed on the first TSVs 303, 304, and 305, respectively, and the connection pads 311, 313, and 315 may be electrically connected to interconnection lines 312, 314, and 316, respectively. Solder balls S3, S4, and S5 or metal electrode pads S3, S4, and S5 may be formed on the interconnection lines 312, 314, and 316, respectively, and thus the base substrate 300 may be electrically connected to the outside.

The connection pads 311, 313, and 315 and the interconnection lines 312, 314, and 316 may be covered by a passivation film 320. The passivation film 320 may be made of an insulating material, and may electrically insulate the connection pads 311, 313, and 315 from the interconnection lines 312, 314, and 316 so that the connection pads 311, 313, and 315 and the interconnection lines 312, 314, and 316 are not directly exposed to the outside.

The base substrate 300 may be electrically connected to the device substrate 100 by a wafer to wafer bonding method. The second cavity area C2 may be a hermetic space formed by bonding the base substrate 300 and the device substrate 100 in a bonding method.

The second cavity area C2 may be formed to have a step with respect to a surface of the base substrate 300. That is, a portion of the surface of the base substrate 300 may be etched to form an empty space, and the empty space may be the second cavity area C2. The second cavity area C2 is formed at a position corresponding to an area in which the device pattern dp is formed on the device substrate 100 so that the second cavity area C2 serves to provide a space in which the device pattern dp can vibrate when the device pattern dp vibrates up, down, left, and right.

One or more second cavity areas C2 may be formed. Since the device pattern dp formed on the device substrate 100 may have a complex shape and one or more areas in which the device pattern dp vibrates may be present, the second cavity areas C2 may be formed to correspond to a position at which the device pattern dp vibrates.

Further, when one or more second cavity areas C2 are formed, the cavity areas may be separated from each other by a second hermetic sealing wall 300s formed by the base substrate 300 and the device substrate 100.

The first TSVs 303 and 304 may be brought into contact with anchors 110 and 111 of the device substrate 100, respectively. The anchors 110 and 111 may serve to support electrodes or structures. Specifically, the anchors 110 and 111 may operate as fixed lateral electrodes.

Further, the first TSV 305 may operate as a vertical electrode. An electrical signal may be applied to the first TSV 305 to drive the device pattern dp thereabove. Similarly, the electrical signal may be applied through the anchors 110 and 111 to drive the device pattern dp. Alternatively, an electrical signal of the device pattern dp may be sensed using the first TSV 305, and the electrical signal of the device pattern dp may be sensed through the anchors 110 and 111.

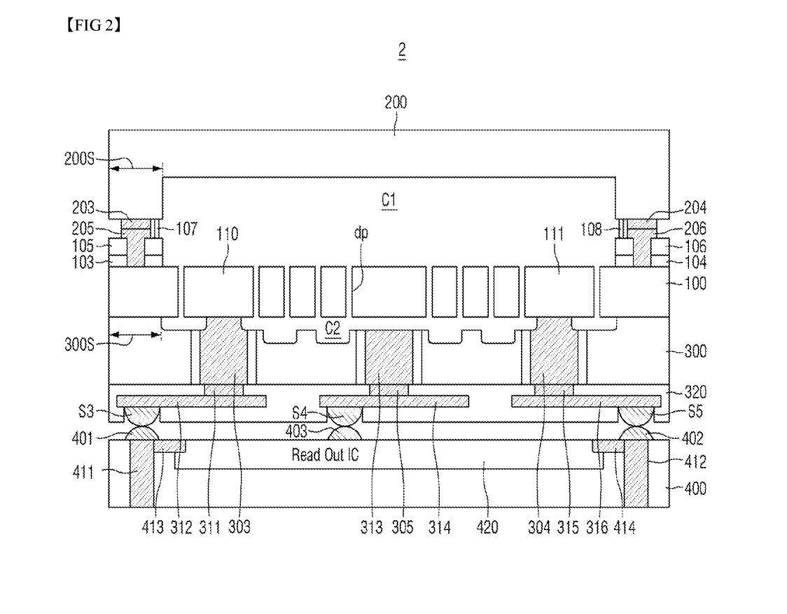

FIG. 2 is a cross-sectional view of a semiconductor package according to another embodiment of the present disclosure. For convenience of description, descriptions of portions which are substantially the same as those of the semiconductor package according to the above embodiment of the present disclosure will be omitted.

Referring to FIG. 2, in comparison to the semiconductor package 1, a semiconductor package 2 according to another embodiment of the present disclosure further includes a circuit substrate 400.

The circuit substrate 400 may be disposed below the base substrate 300, and an integrated circuit (IC) 420 may be formed on the circuit substrate 400 and electrically connected to the first TSVs 303, 304, and 305 formed on the base substrate 300 in order to process an electrical signal for the device pattern dp.

Specifically, the solder balls S3, S4, and S5 respectively formed on the first TSVs 303, 304, and 305 may be electrically connected to the IC 420 through connection bumps 401, 402, and 403 and connection pads 413 and 414.

Further, the semiconductor package 2 further includes second TSVs 411 and 412 formed in the circuit substrate 400.

The second TSVs 411 and 412 may be formed below the second hermetic sealing wall 300s at a position corresponding to a position at which the second hermetic sealing wall 300s of the base substrate 300 is formed. The base substrate 300 may be electrically connected to an outside of the circuit substrate 400 through the second TSVs 411 and 412 to receive an external signal or output a signal to the outside.

Further, in the semiconductor package 2, the circuit substrate 400 may include one or more TSVs. One or more TSVs may be disposed in a point symmetry structure with respect to a center of the circuit substrate 400. When one or more TSVs are disposed in a point symmetry structure, a physical pressure externally applied to the circuit substrate 400 may be uniformly dispersed.

In the semiconductor package 2, the metal pads 203 and 204 and the solder contacts 205 and 206 may include a first material. That is, the metal pads 203 and 204 and the solder contacts 205 and 206 may include the same material, but the present disclosure is not limited thereto. The metal pads 203 and 204 may be brought into contact with the solder contacts 205 and 206 in order to bond the device substrate 100 to the cap substrate 200.

Here, the first material may include, for example, silicon (Si). A melting point of silicon (Si) is 1,410° C.

The solder balls S3, S4, and S5 and the connection bumps 401, 402, and 403 may include a second material. That is, the solder balls S3, S4, and S5 and the connection bumps 401, 402, and 403 may include the same material, but the present disclosure is not limited thereto. The solder balls S3, S4, and S5 may be brought into contact with the connection bumps 401, 402, and 403 in order to bond the base substrate 300 to the circuit substrate 400.

Here, the second material may include, for example, copper (Cu). A melting point of copper (Cu) is 1,084° C.

That is, the first material may be a material having a higher melting point than the second material. For example, the first material may be silicon (Si), nickel (Ni), cobalt (Co), iron (Fe), or the like. A melting point of nickel (Ni) is 1,453° C., a melting point of cobalt (Co) is 1,495° C., and a melting point of iron (Fe) is 1,535° C.

For example, the second material may be copper (Cu), manganese (Mn), or the like. A melting point of manganese (Mn) is 1,246° C.

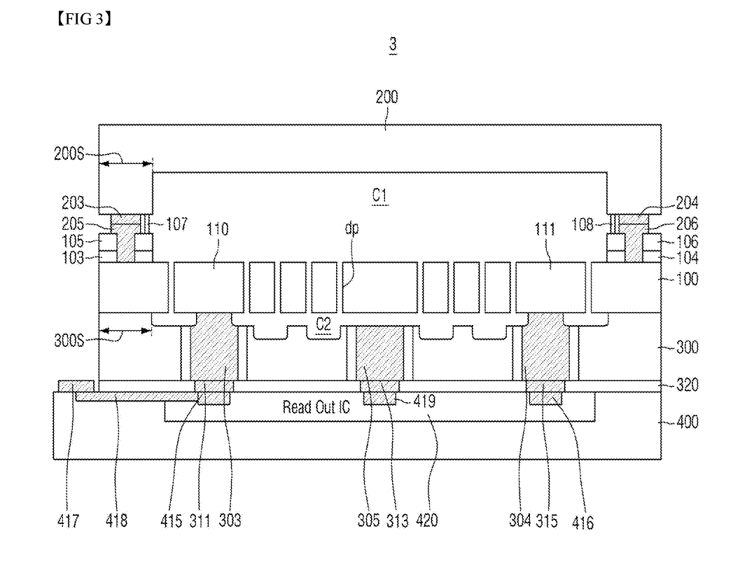

FIG. 3 is a cross-sectional view of a semiconductor package according to still another embodiment of the present disclosure. For convenience of description, descriptions of portions which are substantially the same as those of the semiconductor package according to the above embodiment of the present disclosure will be omitted.

Referring to FIG. 3, in comparison to the semiconductor package 2, in a semiconductor package 3, the base substrate 300 includes first electrode pads 311, 313, and 315 and an insulating layer 320 instead of the interconnection lines 312, 314, and 316 and the solder balls S3, S4, and S5, and the circuit substrate 400 includes second electrode pads 415, 416, and 417 instead of the second TSVs 411 and 412 and the solder balls 401 and 402.

The second electrode pads 415, 416, and 417 may be brought into contact with the first electrode pads 311, 313, and 315, respectively, and the bonding method of the present disclosure may be variously modified and implemented differently from those illustrated. That is, as long as the base substrate 300 can be electrically connected to the circuit substrate 400, the base substrate 300 and the circuit 400 may be modified and implemented in a different form from those illustrated.

FIG. 4 is a cross-sectional view of a semiconductor package according to yet another embodiment of the present disclosure. For convenience of description, descriptions of portions which are substantially the same as those of the semiconductor package according to the above embodiment of the present disclosure will be omitted.

Referring to FIG. 4, in addition to the configuration of the semiconductor package 2, solder balls S5 and S6 may be additionally formed in a semiconductor package 4. The solder balls S5 and S6 may be formed below the circuit substrate 400.

Here, the metal pads 203 and 204 and the solder contacts 205 and 206 may include a first material. That is, the metal pads 203 and 204 and the solder contacts 205 and 206 may include the same material, but the present disclosure is not limited thereto. The metal pads 203 and 204 may be brought into contact with the solder contacts 205 and 206 in order to bond the device substrate 100 to the cap substrate 200.

The first material may include, for example, silicon (Si). A melting point of silicon (Si) is 1,410° C.

The solder balls S3, S4, and S5 and the connection bumps 401, 402, and 403 may include a second material. That is, the solder balls S3, S4, and S5 and the connection bumps 401, 402, and 403 may include the same material, but the present disclosure is not limited thereto. The solder balls S3, S4, and S5 may be brought into contact with the connection bumps 401, 402, and 403 in order to bond the base substrate 300 to the circuit substrate 400.

The second material may include, for example, copper (Cu). A melting point of copper (Cu) is 1,084° C.

That is, the first material may be a material having a higher melting point than the second material. For example, the first material may be silicon (Si), nickel (Ni), cobalt (Co), iron (Fe), or the like. A melting point of nickel (Ni) is 1,453° C., a melting point of cobalt (Co) is 1,495° C., and a melting point of iron (Fe) is 1,535° C.

For example, the second material may be copper (Cu), manganese (Mn), or the like. A melting point of manganese (Mn) is 1,246° C.

The solder balls S6 and S7 may include a third material. The solder balls S6 and S7 may be mounted on another external substrate (e.g., a printed circuit board (PCB)).

The third material may include, for example, gold (Au). A melting point of gold (Au) is 1,064° C. That is, the first material may be a material having a higher melting point than the second material, and the second material may be a material having a higher melting point than the third material.

For example, the third material may be gold (Au), silver (Ag), or the like. A melting point of silver (Ag) is 961° C.

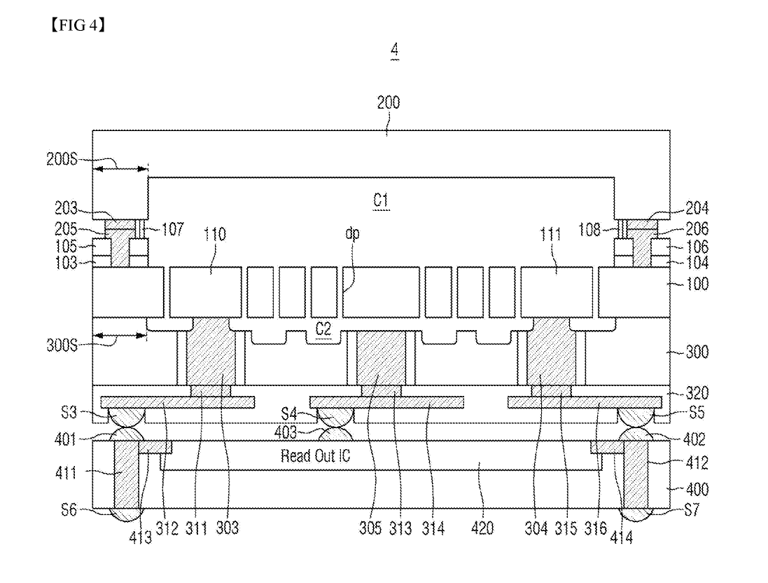

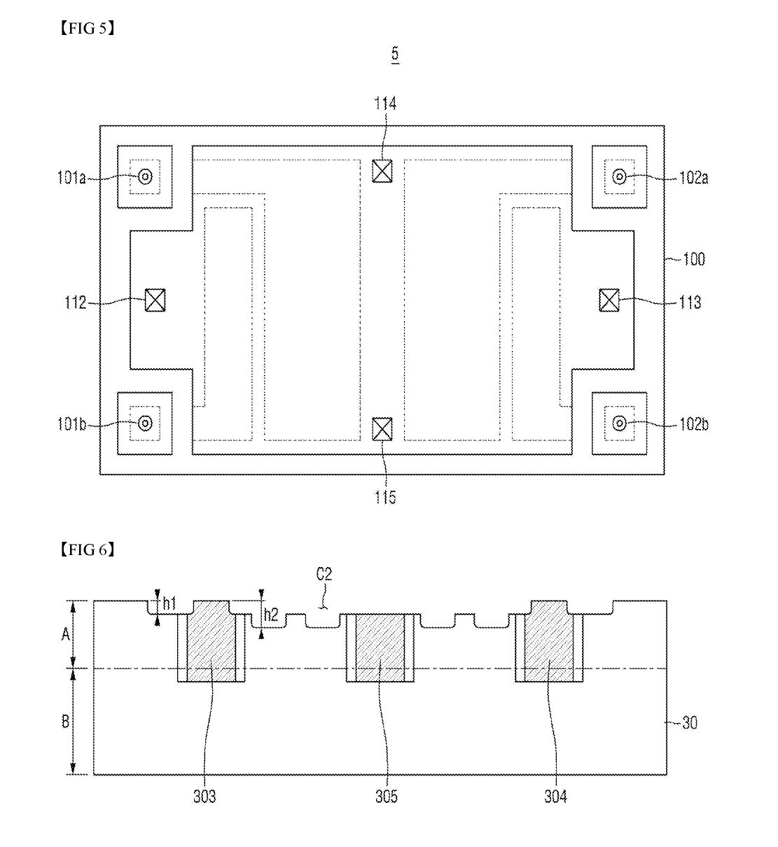

FIG. 5 is a plan view of a semiconductor package according to yet another embodiment of the present disclosure. For convenience of description, descriptions of portions which are substantially the same as those of the semiconductor package according to the embodiment of the present disclosure will be omitted.

Referring to FIG. 5, a semiconductor package 5 may include a plurality of TSVs 101a, 101b, 102a, and 102b formed in the device substrate 100, and the plurality of TSVs 101a, 101b, 102a, and 102b may be disposed in a point symmetry structure with respect to a center of the device substrate 100. When the plurality of TSVs 101a, 101b, 102a, and 102b are disposed in a point symmetry structure, a physical pressure externally applied to the device substrate 100 may be uniformly dispersed, and the device pattern dp in the device substrate 100 may be safely protected.

The plurality of TSVs 101a, 101b, 102a, and 102b may be disposed in the point symmetry structure to improve durability of the semiconductor package 5.

In FIG. 5, a plurality of anchors 112 to 115 are also illustrated. A support spring of a frame may be attached to a side wall of each of the anchors 112 to 115.

Hereinafter, a method of manufacturing the semiconductor package 1 according to an embodiment of the present disclosure will be described.

FIGS. 6 to 13 are views illustrating intermediate steps for describing a method of manufacturing the semiconductor device according to an embodiment of the present disclosure.

Referring to FIG. 6, first, recesses are formed on an upper portion of a bulk base substrate 30, and first TSVs 303, 304, and 305 are formed by filling the recesses. Then, the bulk base substrate 30 is patterned to form a second cavity area C2. In FIG. 6, an area B is an area which will be removed in a subsequent chemical mechanical polishing (CMP) process, and a remaining area A forms a base substrate 300. The bulk base substrate 30 may include, for example, silicon (Si).

For example, a recessed depth h1 may be 2 μm and a depth h2 in which a second cavity area C2 is formed may be 20 μm, but the present disclosure is not limited thereto.

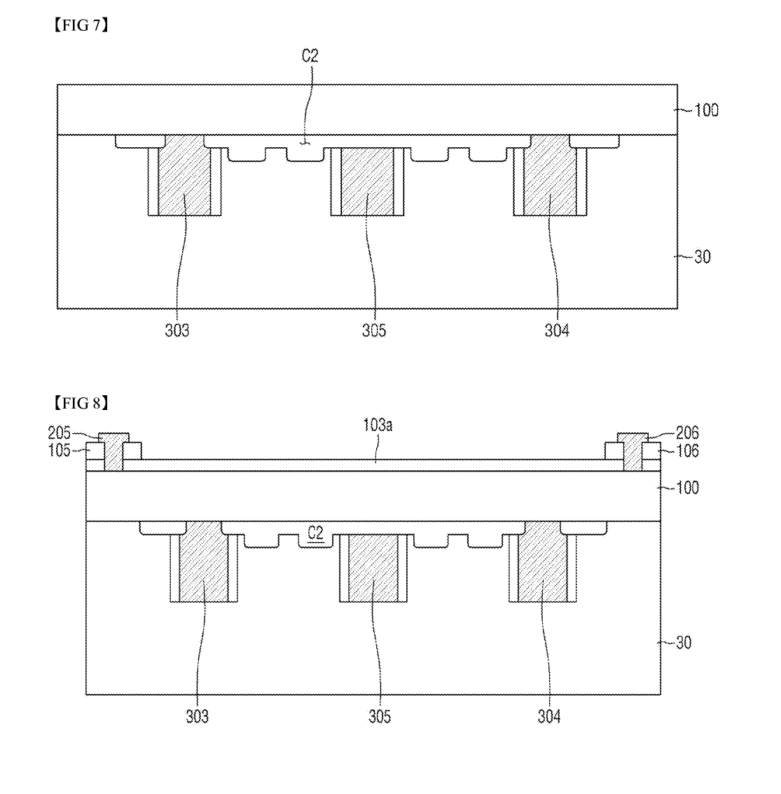

Referring to FIG. 7, a device substrate 100 is bonded to the upper portion of the bulk base substrate 30. The bulk base substrate 30 and the device substrate 100 may be electrically connected by a wafer to wafer bonding method. A height of the device substrate 100 may be, for example, 30 μm, but the present disclosure is not limited thereto.

Referring to FIG. 8, a passivation layer 103a is formed on the device substrate 100, and solder pads 105 and 106 are formed on the passivation layer 103a. The passivation layer 103a and the solder pads 105 and 106 are patterned to form vias, and solder contacts 205 and 206 are formed by filling the vias.

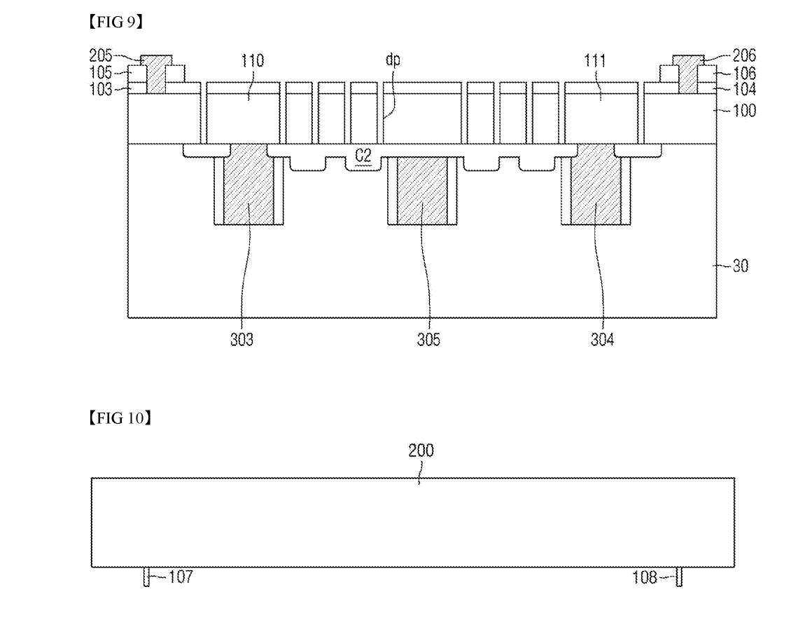

Referring to FIG. 9, the passivation layer 103a is patterned, and the device substrate 100 is patterned using the passivation layer 103a as a mask in order to form a device pattern dp.

In this case, the device pattern dp may be formed using a lithography process, a dry etching process, a striping process, a cleaning process, and the like.

Referring to FIG. 10, a cap substrate 200 is prepared, and hard stop materials (HSM) 107 and 108 are formed on the cap substrate 200.

For example, a height of the cap substrate 200 may be 300 μm, but the present disclosure is not limited thereto.

Referring to FIG. 11, a seed layer is formed on the cap substrate 200, and metal pads 203 and 204 are formed by performing electroplating on the seed layer.

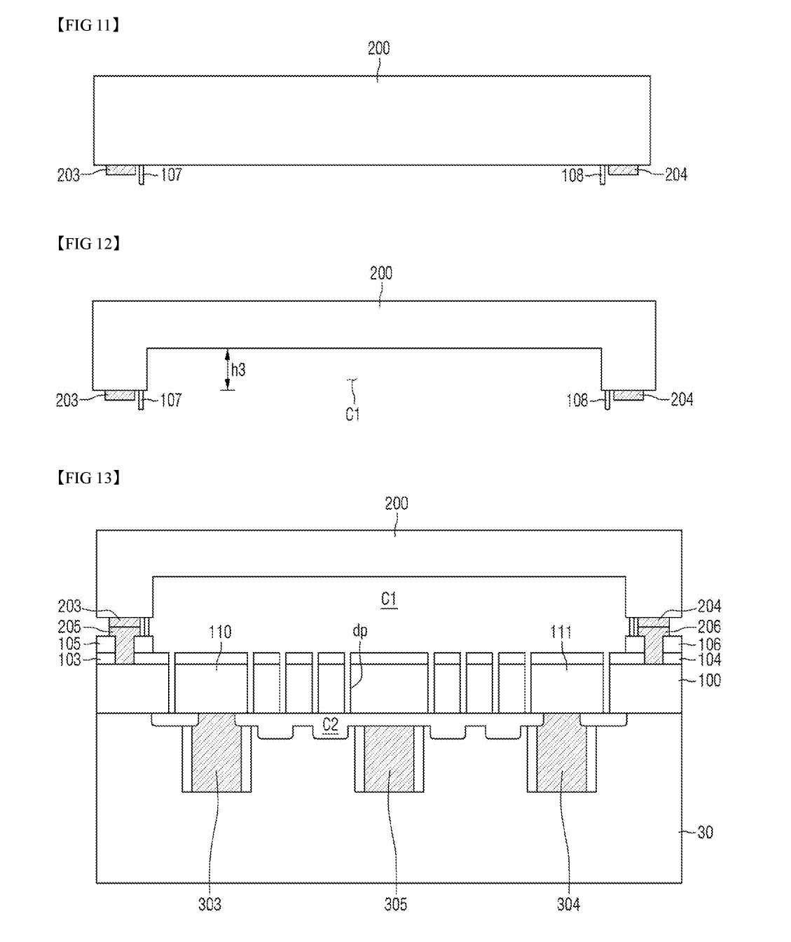

Referring to FIG. 12, a first cavity area C1 is formed in the cap substrate 200 by a patterning process using a mask. The first cavity area C1 may be formed at a position corresponding to a center area of the device substrate 100.

A depth h3 of the first cavity area C1 may range from 20 μm to 30 μm, but the present disclosure is not limited thereto.

Referring to FIG. 13, the cap substrate 200 of FIG. 12 is bonded to the device substrate 100 of FIG. 9 using a wafer to wafer bonding method. In this case, a eutectic bonding process may be performed after a pre-treatment process is performed in the bonding process, but the present disclosure is not limited thereto. After the bonding process in FIG. 13 is performed, the area B (see FIG. 6) of the bulk base substrate 30 is removed by a CMP process to form the base substrate 300 as illustrated in FIG. 1.

According to the semiconductor package of the present disclosure, a base substrate and an IC substrate can be directly connected using a wafer to wafer bonding method by forming a TSV on the base substrate so that an electric signal transmission path between an inside of a device pattern and an outside of the IC substrate can be minimized. Therefore, a signal-to-noise ratio (SNR) with respect to an external inflow noise can be improved and electrical contact reliability of the electric signal transmission path can be improved.

Further, a total size of the semiconductor package can be reduced and durability of the semiconductor package can be improved.

The above description of the disclosure is only exemplary, and it will be understood by those skilled in the art that various modifications can be made without departing from the scope of the present disclosure and without changing essential features. Therefore, the above-described embodiments should be considered in a descriptive sense only and not for purposes of limitation.

What is claimed is:

1. A semiconductor package comprising:
a device substrate having a device pattern formed thereon;
a cap substrate disposed above the device substrate and including a first cavity area;
a base substrate disposed below the device substrate and including a second cavity area formed at a position corresponding to the first cavity area and at least one first through-silicon via (TSV) configured to output an electrical signal provided from the device pattern to the outside or transmit an electrical signal provided from the outside to the device pattern; and
a circuit substrate disposed below the base substrate, electrically connected to the first TSV, and configured to process an electrical signal for the device pattern,
wherein the second cavity area is formed by the first TSV being in direct contact with a lower portion of the device substrate.

2. The semiconductor package of claim 1, wherein:
the first cavity area is formed to have a step with respect to a surface of the cap substrate; and
the second cavity area is formed to have a step with respect to a surface of the base substrate.

3. The semiconductor package of claim 1, further comprising a metal pad disposed between the cap substrate and the device substrate and configured to bond the cap substrate to the device substrate.

4. The semiconductor package of claim 3, further comprising a first solder ball disposed between the base substrate and the circuit substrate and configured to electrically connect the base substrate to the circuit substrate.

5. The semiconductor package of claim 4, wherein a melting point of a material which forms the metal pad is higher than a melting point of a material which forms the first solder ball.

6. The semiconductor package of claim 5, further comprising a second solder ball disposed below the circuit substrate,
wherein the melting point of the material which forms the first solder ball is higher than a melting point of a material which forms the second solder ball.

7. The semiconductor package of claim 1, wherein the device substrate and the base substrate are electrically connected by a wafer to wafer bonding method.

8. The semiconductor package of claim 1, wherein the first cavity area includes one or more cavity areas and the one or more cavity areas are separated by a first hermetic sealing wall formed by the cap substrate and the device substrate.

9. The semiconductor package of claim 1, wherein at least one vertical electrode is formed in the second cavity area.

10. The semiconductor package of claim 9, wherein the second cavity area includes one or more cavity areas and the one or more cavity areas are separated by a second hermetic sealing wall formed by the device substrate and the base substrate.

11. A semiconductor package comprising:
a device substrate having a device pattern formed thereon;
a cap substrate disposed above the device substrate and including first cavity areas formed therein;
a base substrate disposed below the device substrate and including second cavity areas and a first through-silicon via (TSV) formed therein; and
a circuit substrate disposed below the base substrate and including a second TSV formed therein,
wherein:
the first cavity areas are separated from each other by a first hermetic sealing wall formed by the cap substrate and the device substrate;
the second cavity areas are separated from each other by a second hermetic sealing wall formed by the device substrate and the base substrate; and
the first TSV is formed to be in direct contact with the device substrate.

12. The semiconductor package of claim 11, wherein the second TSV includes a plurality of TSVs and the plurality of TSVs are disposed in a point symmetry structure with respect to a center of the circuit substrate.

13. The semiconductor package of claim 11, wherein the first TSV and the second TSV are electrically connected.

14. The semiconductor package of claim 11, wherein:
the first cavity area is formed to have a step with respect to a surface of the cap substrate; and
the second cavity area is formed to have a step with respect to a surface of the base substrate.

15. The semiconductor package of claim 11, wherein the first cavity area is a hermetic space formed by bonding the cap substrate and the device substrate using a wafer to wafer bonding method.

16. The semiconductor package of claim 15, wherein:
the second cavity area is a hermetic space formed by bonding the device substrate and the base substrate using a wafer to wafer bonding method; and
an inside and an outside of the second cavity area are electrically connected using the first TSV.

17. The semiconductor package of claim 16, wherein the base substrate and the circuit substrate are electrically connected by a wafer to wafer bonding method, and an electrical signal generated from the device pattern is output through the second TSV.

18. The semiconductor package of claim 11, wherein the circuit substrate includes a readout integrated circuit (IC) configured to process an electrical signal for the device pattern.
